(19) United States
(12) Patent Application Publication
(10) Pub. No.: US 2026/0324091 A1
(43) Pub. Date: Oct. 15, 2026

(54) SEMICONDUCTOR DEVICE AND METHOD OF MANUFACTURING SEMICONDUCTOR DEVICE

(71) Applicant: WUHAN XINXIN SEMICONDUCTOR MANUFACTURING CO., LTD., WUHAN (CN)

(72) Inventor: KAIWEI CAO, WUHAN (CN)

(21) Appl. No.: 19/635,812

(22) Filed: Apr. 1, 2026

(30) Foreign Application Priority Data
Apr. 10, 2025 (CN) 202510450593.X

(51) Int. Cl. H10D 89/10; H10D 62/10; H10W 10/00; H10W 10/17

(52) U.S. Cl. CPC H10D 89/10; H10D 62/126; H10W 10/0145; H10W 10/17

(57) ABSTRACT

A method of manufacturing a semiconductor device includes: providing a semiconductor substrate, including a cell region and a periphery region; reducing a height of a portion of the semiconductor substrate in the periphery region, forming a plurality of first trenches in the portion of the semiconductor substrate in the periphery region; forming a plurality of second trenches in a portion of the semiconductor substrate in the cell region; forming an isolation structure that fills the first trenches and the second trenches. The first trenches divide the portion of the semiconductor substrate in the periphery region into a plurality of periphery active areas; the second trenches divide the portion of the semiconductor substrate in the cell region into a plurality of cell active areas. A height of the plurality of cell active areas is greater than a height of the plurality of periphery active areas.

### CROSS REFERENCE TO RELATED APPLICATIONS

The present application claims the priority of the Chinese patent application No. 202510450593.X, filed on Apr. 10, 2025, contents of which are incorporated herein by its entireties.

### TECHNICAL FIELD

Embodiments of the present disclosure relate to the technical field of semiconductors, and more specifically, to a method of manufacturing a semiconductor device and a semiconductor device.

### BACKGROUND

In application of integrated circuits, performance of various semiconductor devices is affected by manufacturing processes of various regions. Since the manufacturing processes of the various regions may be different from each other, final morphology of the semiconductor devices may be affected, such that the performance may be affected.

In practice, the inventor of the present application discovers that, in current semiconductor device manufacturing schemes, formation of an active area corresponding to a cell region and formation of an active area corresponding to a periphery region may not be performed synchronously. Therefore, subsequent processes may be needed, and it may be inevitable to perform processing on various regions. In this way, a damage may be caused to a region that does not need to be processed, or the region that does not need to be processed needs to be shielded. Therefore, the performance of the semiconductor device may be affected, or complexity of manufacturing processes may be improved.

### SUMMARY

In a first aspect, the present disclosure provides a method of manufacturing a semiconductor device, including: providing a semiconductor substrate, the semiconductor substrate including a cell region and a periphery region; reducing a height of a portion of the semiconductor substrate in the periphery region, forming a plurality of first trenches in the portion of the semiconductor substrate in the periphery region; forming a plurality of second trenches in a portion of the semiconductor substrate in the cell region; forming an isolation structure that fills the plurality of first trenches and the plurality of second trenches. The plurality of first trenches divide the portion of the semiconductor substrate in the periphery region into a plurality of periphery active areas; the plurality of second trenches divide the portion of the semiconductor substrate in the cell region into a plurality of cell active areas. A height of the plurality of cell active areas is greater than a height of the plurality of periphery active areas.

In a second aspect, the present disclosure provides a semiconductor device, including: a semiconductor substrate, including a cell region and a periphery region; a plurality of first trenches, defined in a portion of the semiconductor substrate in the periphery region and dividing the portion of the semiconductor substrate in the periphery region into a plurality of periphery active areas; a plurality of second trenches, defined in a portion of the semiconductor substrate in the cell region and dividing the portion of the semiconductor substrate in the cell region into a plurality of cell active areas; and an isolation structure, filled in the plurality of first trenches and the plurality of second trenches. A height of the plurality of cell active areas is greater than a height of the plurality of periphery active areas.

### BRIEF DESCRIPTION OF THE DRAWINGS

To more clearly illustrate technical solutions in the embodiments of the present disclosure or the related art, the accompanying drawings needed for describing the embodiments of the present disclosure or the related art will be briefly introduced in the following. Obviously, the drawings in the following description are only some embodiments of the present disclosure, and any ordinary skilled person in the art may obtain other drawings based on these drawings without creative work.

FIG. 1 is a flow chart of a method of manufacturing a semiconductor device according to an embodiment of the present disclosure.

FIG. 2 is a structural schematic view of a semiconductor substrate according to embodiment of the present disclosure.

FIG. 3A is a structural schematic view of a height of a portion of the semiconductor substrate in a periphery region being reduced, according to an embodiment of the present disclosure.

FIG. 3B is a perspective view of the semiconductor substrate shown in FIG. 3A, being viewed from a first viewing angle, according to an embodiment of the present disclosure.

FIG. 4A is a structural schematic view of a well formed according to an embodiment of the present disclosure.

FIG. 4B is a perspective view of the well shown in FIG. 4A, being viewed from a first viewing angle, according to an embodiment of the present disclosure.

FIG. 5A is a structural schematic view of forming a second mask layer according to an embodiment of the present disclosure.

FIG. 5B is a perspective view of the second mask layer shown in FIG. 5A, being viewed from a first viewing angle, according to an embodiment of the present disclosure.

FIG. 6A is a structural schematic view of forming a plurality of first trenches according to an embodiment of the present disclosure.

FIG. 6B is a perspective view of the plurality of first trenches shown in FIG. 6A, being viewed from a second viewing angle, according to an embodiment of the present disclosure.

FIG. 7A is a structural schematic view of removing the second mask layer from the cell region according to an embodiment of the present disclosure.

FIG. 7B is a perspective view of the cell region having the second mask layer removed as shown in FIG. 7A, being viewed from a second viewing angle, according to an embodiment of the present disclosure.

FIG. 8A is a structural schematic view of forming a photoresist layer according to an embodiment of the present disclosure.

FIG. 8B is a perspective view of the photoresist layer as shown in FIG. 8A, being viewed from a first viewing angle, according to an embodiment of the present disclosure.

FIG. 9A is a structural schematic view of forming a plurality of second trenches according to an embodiment of the present disclosure.

FIG. 9B is a perspective view of the plurality of second trenches as shown in FI 9A, being viewed from a first viewing angle, according to an embodiment of the present disclosure.

FIG. 10A is a structural schematic view of forming an isolation structure according to an embodiment of the present disclosure.

FIG. 10B is a perspective view of the isolation structure as shown in FIG. 10A, being viewed from a first viewing angle, according to an embodiment of the present disclosure.

Reference numerals in the drawings: semiconductor substrate 100, first well 110, second well 120, drift region 130, third well 140, isolation structure 150, first trench 101, first sub-trench 1011, second sub-trench 1012, second trench 102, third trench 103, first mask layer 200, second mask layer 300, photoresist layer 400, cell region C, array active area C1, periphery region P, first type area P1, first type active area P11, second type area P2, second type active area P21, third type area P3, third type area I P31, third type area II P32, third type active area I P311, third type active area II P321.

### DETAILED DESCRIPTIONS

Technical solutions in the embodiments of the present disclosure will be clearly and completely described by referring to the accompanying drawings. Obviously, the described embodiments are only a part of, not all of, the embodiments of the present disclosure. All other embodiments, which are obtained by any ordinary skilled person in the art based on the embodiments of the present disclosure without creative work, shall fall within the scope of the present disclosure.

For a method of manufacturing semiconductor devices in the art, different operations may be performed on a cell region of a storage array and on a periphery region of a logic control device, such that an active area of the cell region and an active area of the periphery region may be formed. Therefore, it may be inevitable to perform different processes on different regions. A damage may be caused to a region that does not need to be processed, or the region that does not need to be processed may be shielded, such that the performance of the semiconductor device may be affected, or complexity of manufacturing processes may be improved.

Therefore, the present disclosure provides a method of manufacturing the semiconductor device. The semiconductor substrate may include a cell region and a periphery region. A height of a portion of the semiconductor substrate in the periphery region may be reduced. A first mask layer and a second mask layer may be formed on the semiconductor substrate. A plurality of first trenches may be formed in the portion of semiconductor substrate in the periphery region. The second mask layer in the cell region may be removed. A plurality of second trenches may be formed in the portion of the semiconductor substrate in the cell region. An isolation material may be formed to fill the plurality of first trenches and the plurality of second trenches and cover surfaces of the cell region and the periphery region. The height of the periphery region and the height of the cell region may be reduced, enabling an upper surface of the second mask layer in the periphery region to be aligned and flush with an upper surface of the portion of the semiconductor substrate in the cell region. That is, the present disclosure provides a method of forming the active area of the cell region and forming the active area of the periphery region, and a storage array, which will be subsequently formed, may be integrated into traditional logic processes.

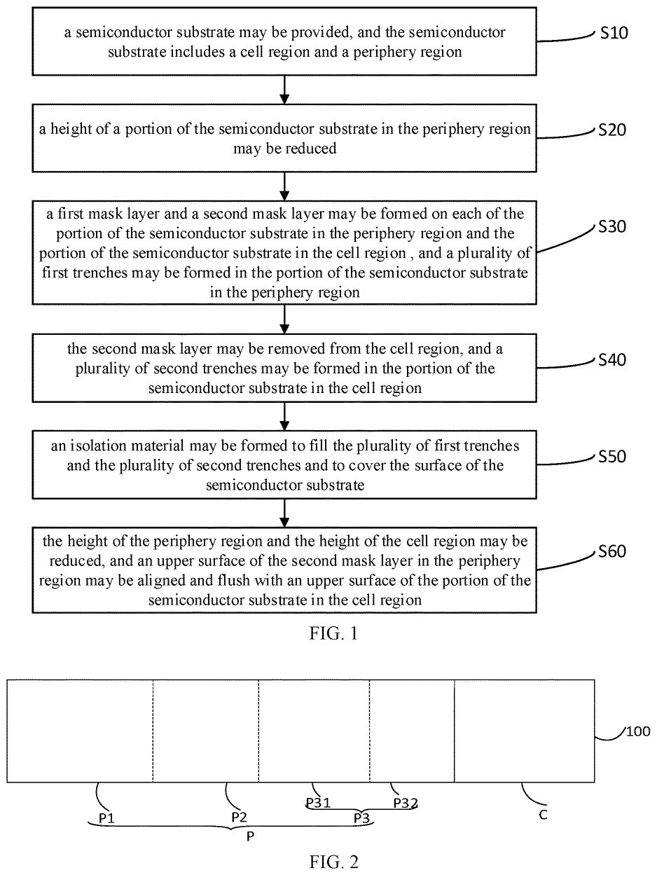

As shown in FIG. 1, FIG. 1 is a flow chart of a method of manufacturing a semiconductor device according to an embodiment of the present disclosure.

As shown in FIG. 1, the method of manufacturing the semiconductor device of the present disclosure may include the following operations.

In an operation S10, a semiconductor substrate may be provided, and the semiconductor substrate includes a cell region and a periphery region.

The semiconductor substrate may be any suitable substrate known in the art. The cell region may refer to a region on which a memory array is to be formed subsequently. The periphery region may refer to a region on which logic control devices are to be formed subsequently.

Specifically, the semiconductor substrate may be provided, and the semiconductor substrate may be divided into the cell region and the periphery region.

In an operation S20, a height of a portion of the semiconductor substrate in the periphery region may be reduced.

Since different devices may be formed subsequently in the periphery region and in the cell region, requirements for an active area of the periphery region may be different from requirements for an active area of the cell region.

Specifically, for the semiconductor substrate divided into the periphery region and the cell region, a first etching may be performed on the portion of the semiconductor substrate in the periphery region, such that the height of the portion of the semiconductor substrate in the periphery region may be reduced. Therefore, an upper surface of the portion of the semiconductor substrate in the periphery region may be lower than a surface of a portion of the semiconductor substrate in the cell region. That is, the height of the portion of the semiconductor substrate in the periphery region may be reduced, enabling the height of the portion of the semiconductor substrate in the periphery region to be different from a height of the portion of the semiconductor substrate in the cell region. In this way, the periphery region may be distinguished from the cell region, facilitating different processing operations to be performed on the periphery region and the cell region.

In an operation S30, a first mask layer and a second mask layer may be formed on each of the portion of the semiconductor substrate in the periphery region and the portion of the semiconductor substrate in the cell region, and a plurality of first trenches may be formed in the portion of the semiconductor substrate in the periphery region.

The first mask layer and the second mask layer may be configured to cover a surface of the semiconductor substrate. The first mask layer may be an oxide layer, and the second mask layer may be a nitride layer. Each of the plurality of first trenches may refer to a trench of a certain depth being formed in the portion of the semiconductor substrate in the periphery region, and the portion of the semiconductor substrate in the periphery region may be divided into a plurality of periphery active areas via the plurality of first trenches. The periphery active area may refer to the active area formed in the periphery region.

Specifically, after reducing the height of the portion of the semiconductor substrate in the periphery region, the first mask layer may be formed and may cover both the portion of the semiconductor substrate in the periphery region and the portion of the semiconductor substrate in the cell region. Furthermore, the second mask layer may be formed to cover the first mask layer. For the portion of the semiconductor substrate in the periphery region, etching may be performed to form the plurality of first trenches. That is, a second etching may be performed on the portion of the semiconductor substrate in the periphery region, such that the plurality of first trenches may be formed in the portion of the semiconductor substrate in the periphery region, and portions of the semiconductor substrate formed by being divided by the plurality of first trenches may serve as the periphery active area.

In some embodiments, after forming the plurality of first trenches, the periphery active area may be formed in the periphery region through division of the plurality of first trenches

In an operation S40, the second mask layer may be removed from the cell region, and a plurality of second trenches may be formed in the portion of the semiconductor substrate in the cell region.

Each of the plurality of second trenches may refer to a trench of a certain depth formed in the portion of the semiconductor substrate in the cell region.

Specifically, the second mask layer may be removed from the cell region, and etching may be performed on the portion of the semiconductor substrate in the cell region to form the plurality of second trenches in the portion of the semiconductor substrate in the cell region. Portions of the semiconductor substrate formed by being divided by the plurality of second trenches may serve as a cell active area (CAA).

In an operation S50, an isolation material may be formed to fill the plurality of first trenches and the plurality of second trenches and to cover the surface of the semiconductor substrate.

The isolation material may be any suitable isolation material known in the art.

Specifically, after forming the plurality of first trenches and the plurality of second trenches, the isolation material may be filled into the plurality of first trenches and the plurality of second trenches. The isolation material may be higher than the semiconductor substrate and cover the surface of the semiconductor substrate.

In an operation S60, the height of the periphery region and the height of the cell region may be reduced, and an upper surface of the second mask layer in the periphery region may be aligned and flush with an upper surface of the portion of the semiconductor substrate in the cell region.

The second mask layer may be retained in the periphery region, whereas the second mask layer in the cell region may have been removed. In order to ensure the upper surface of the second mask layer in the periphery region to be aligned and flush with the upper surface of the portion of the semiconductor substrate in the cell region, the height of the periphery region and the height of the cell region may both be reduced.

Specifically, after filling the isolation material, at least part of the isolation material and the first mask layer may be removed, such that the portion of the semiconductor substrate in the cell region may be exposed, and the upper surface of the second mask layer in the periphery region may be aligned and flush with the upper surface of the portion of the semiconductor substrate in the cell region.

In the present embodiment, the semiconductor substrate may be divided into the cell region and the periphery region, the height of the portion of the semiconductor substrate in the periphery region may be reduced. The first mask layer and the second mask layer may be formed on the semiconductor substrate. The plurality of first trenches may be formed in the portion of the semiconductor substrate in the periphery region. The second mask layer in the cell region may be removed. The plurality of second trenches may be formed in the portion of the semiconductor substrate in the cell region. The isolation material may be formed to fill the plurality of first trenches and the plurality of second trenches and cover the surfaces of the cell region and the periphery region. The height of the periphery region and the height of the cell region may be reduced, such that the upper surface of the second mask layer in the periphery region may be aligned and flush with the upper surface of the portion of the semiconductor substrate in the cell region. In the present embodiment, a method of forming the active areas of the cell region and the active areas of the periphery region is provided, such that the memory array, which may be formed subsequently, may be integrated into traditional logic processes.

The present disclosure will be described in the following by referring to the drawings.

In some embodiments, the operation of S10 may be as follows.

The semiconductor substrate may be provided, and the semiconductor substrate may be divided into the cell region and the periphery region.

As shown in FIG. 2, FIG. 2 is a structural schematic view of the semiconductor substrate according to an embodiment of the present disclosure.

As shown in FIG. 2, the semiconductor substrate 100 may be provided, and the semiconductor substrate may be divided into the periphery region P and the cell region C.

In some embodiments, the periphery region P may further be divided into a first type area P1, a second type area P2, and a third type area P3. The third type area P3 may further be divided into a third type area I P31 and a third type area II P32. Areas of different types may have different functions. For example, the area may be divided based on voltage values, positions, and so on, which may be determined based on actual circumstances.

In some embodiments, the operation S20 of reducing the height of the portion of the semiconductor substrate in the periphery region may include following operations.

Firstly, the height of the portion of the semiconductor substrate in the periphery region may be reduced, enabling the portion of the semiconductor substrate in the periphery region to be lower than that of the portion of the semiconductor substrate in the cell region.

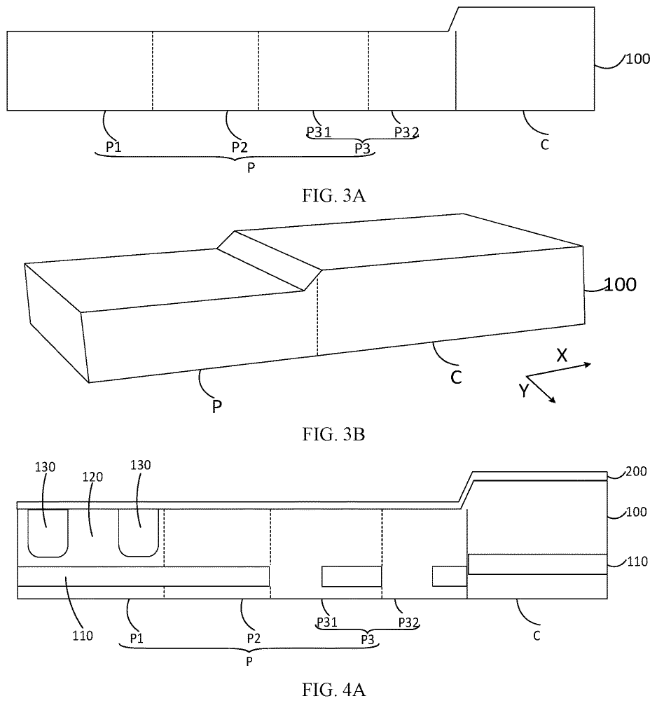

As shown in FIGS. 3A and 3B, FIG. 3A is a structural schematic view of the height of the portion of the semiconductor substrate in the periphery region being reduced, according to an embodiment of the present disclosure; and FIG. 3B is a perspective view of the semiconductor substrate shown in FIG. 3A, being viewed from a first viewing angle, according to an embodiment of the present disclosure.

As shown in FIGS. 3A and 3B, based on FIG. 2, the portion of the semiconductor substrate in the periphery region P may be etched to reduce the height of the portion of the semiconductor substrate 100 in the periphery region P, and the height of the portion of the semiconductor substrate in the cell region 100 remains unchanged.

The first direction may be an X direction, and the second direction may be a Y direction. FIG. 3A includes a cross-sectional view of the periphery region P in the second direction and a cross-sectional view of the cell region C in the first direction. In the periphery region P, a cross-sectional view of the first type area P1 taken along the second direction, a cross-sectional view of the second type area P2 taken along the second direction, and a cross-sectional view of the third type area P3 taken along the second direction may be shown.

In some embodiments, the third type area P3 may be divided into the third type area I P31 and the third type area II P32. In this case, in the periphery region P, a cross-sectional view of the third type area I P31 taken along the second direction and a cross-sectional view of the third type area II P32 taken along the second direction may be shown.

It may be understood that, before etching the portion of the semiconductor substrate in the periphery region P, a protective layer may be formed on the semiconductor substrate 100 to protect the portion of the semiconductor substrate in the cell region C. After reducing the height of the portion of the semiconductor substrate in the periphery region P, the protective layer of the cell region C may be removed.

In some embodiments, the operation S30, in which the first mask layer and the second mask layer may be formed on the portion of the semiconductor substrate in the periphery region and the portion of the semiconductor substrate in the cell region, and the plurality of first trenches may be formed in the portion of the semiconductor substrate in the periphery region, may include following operations.

Firstly, the first mask layer may be formed.

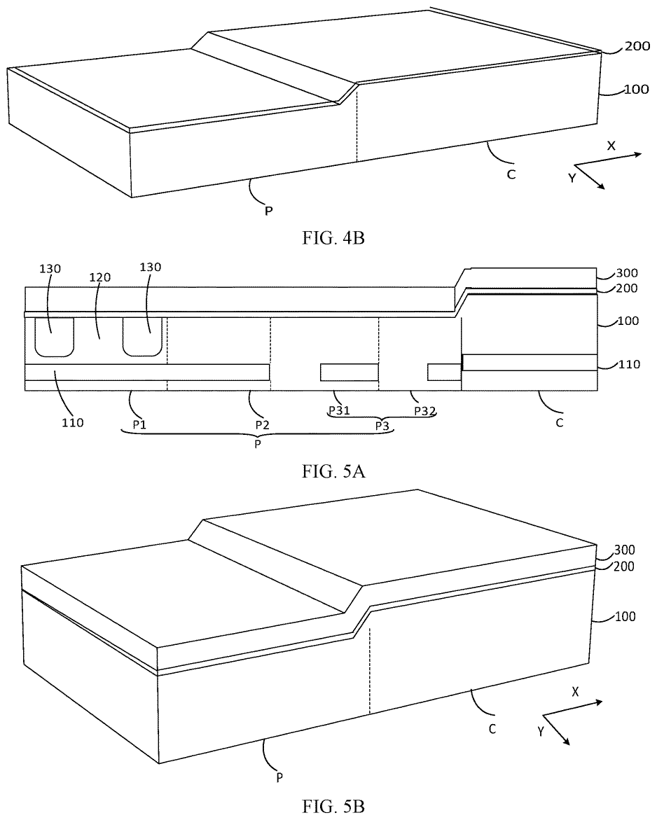

As shown in FIGS. 4A and 4B, FIG. 4A is a structural schematic view of a well formed according to an embodiment of the present disclosure; and FIG. 4B is a perspective view of the formed well shown in FIG. 4A, being viewed from a first viewing angle, according to an embodiment of the present disclosure.

Specifically, as shown in FIGS. 4A and 4B, based on FIGS. 3A and 3B, the first mask layer 200 may be formed to cover the portion of the semiconductor substrate in the periphery region P and the portion of the semiconductor substrate in the cell region C.

The first mask layer may be an oxide layer, such as silicon oxide.

In an embodiment, a doped region may be formed in the portion of the semiconductor substrate 100 in the periphery region P. FIG. 4A shows an embodiment where the doped region is formed in the semiconductor substrate.

Subsequently, the second mask layer may be formed to cover the first mask layer.

As shown in FIGS. 5A and 5B, FIG. 5A is a structural schematic view of forming the second mask layer according to an embodiment of the present disclosure; and FIG. 5B is a perspective view of the formed second mask layer shown in FIG. 5A, being viewed from a first viewing angle, according to an embodiment of the present disclosure.

As shown in FIGS. 5A and 5B, specifically, based on FIGS. 4A and 4B, the second mask layer 300 may be formed to cover the first mask layer 200. The second mask layer 300 may be a nitride layer, such as silicon nitride.

In some embodiments, before forming the second mask layer 300, since the surface of the semiconductor substrate 100 may be damaged after forming various doped regions, the first mask layer may be removed firstly, and a new first mask layer 200 may be reformed, and then the second mask layer 300 may be formed.

Furthermore, the plurality of first trenches may be formed in the portion of the semiconductor substrate in the periphery region.

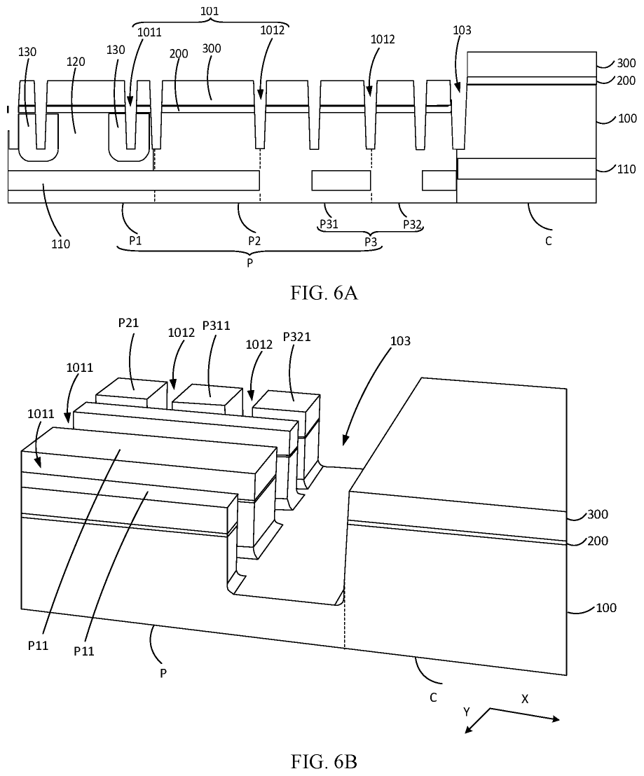

As shown in FIGS. 6A and 6B, FIG. 6A is a structural schematic view of forming the plurality of first trenches according to an embodiment of the present disclosure; and FIG. 6B is a perspective view of the formed plurality of first trenches shown in FIG. 6A, being viewed from a second viewing angle, according to an embodiment of the present disclosure.

As shown in FIGS. 6A and 6B, based on FIGS. 5A and 5B, the plurality of first trenches 101 may be formed in the periphery region P from the second mask layer 300 towards the semiconductor substrate 100.

Furthermore, the plurality of first trenches 101 may include a plurality of first sub-trenches 1011 and a plurality of second sub-trenches 1012. Each of the plurality of first sub-trenches 1011 extend along a first direction, and each of the plurality of second sub-trenches 1012 may extend along a second direction. The plurality of first sub-trenches 1011 and the plurality of second sub-trenches 1012 may be located in different regions of the periphery region P.

In addition, the plurality of first sub-trenches 1011 may be located in the first type area P1 of the periphery region P and may divide the first type area P1 of the semiconductor substrate into a plurality of first type active area P11 extending along the first direction. The plurality of second sub-trenches 1012 may be located in the second type area P2 and third type area P3 of the periphery region P. The plurality of second sub-trenches 1012 may respectively divide the second type area P2 and the third type area P3 of the semiconductor substrate into a second type active area P21 and third type active areas P311 and P321, correspondingly.

Specifically, the first trench 101 may include the plurality of first sub-trenches 1011 and the plurality of second sub-trenches 1012. In this way, the plurality of first sub-trenches 1011 may be formed and may be located in the first type area P1. Each of the plurality of first sub-trenches 1011 may extend along the first direction. The plurality of first sub-trenches 1011 may divide the first type area P1 of the semiconductor substrate into the plurality of periphery active areas extending along the first direction. For example, the periphery active areas formed by dividing the first type area P1 may be denoted as the first type active areas. In some embodiments, the first type area P1 of the semiconductor substrate may be divided by the plurality of first sub-trenches 1011 into the plurality of first type active areas P11 extending along the first direction. As shown in FIG. 6B, three first sub-trenches 1011 may divide the first type area P1 of the semiconductor substrate into three first type active areas P11.

Furthermore, the plurality of second sub-trenches 1012 may be formed and may be located in the second type area P2 and the third type area P3. Each of the plurality of second sub-trenches 1012 may extend along the second direction to divide the second type area P2 and the third type area P3 of the semiconductor substrate into the plurality of periphery active areas extending along the second direction. The third type area P3 may further be divided into a third type area I P31 and a third type area II P32. In this case, the periphery active area formed by dividing the second type area P2 may be the second type active area P21, the periphery active area formed by dividing the third type area P31 may be the third type active area I P311, the periphery active area formed by dividing the third type second area two P32 may be the third type active area II P321. In this way, the second type area P2 and the third type area P3 may be divided by the plurality of second sub-trenches 1012 into the second type active area P21, the third type active area I P311, and the third type active area II P321.

In an embodiment, as shown in FIG. 6A, the plurality of first type active areas P11, one second type active area P21, two third type active areas I P311, two third type active areas II P321, and the cell region C. In FIG. 6B, the plurality of first type active areas P11 extending along the first direction, one second type active area P21, one third type active area I P311, one third type active area II P321, and the cell region C may be formed. The third type active area I P311 and the third type active area II P321 that are additionally shown in FIG. 5A may be visible in FIG. 5B only when extended in the second direction.

Furthermore, when forming the plurality of first trenches, following operations may further be included.

A third trench may be formed and may extend along the second direction to divide the cell region from the periphery region of the semiconductor substrate.

As shown in FIGS. 6A and 6B, the third trench 103 may be formed between the periphery region P and the cell region C. The third trench 103 may extend along the second direction to divide the portion of the semiconductor substrate in the periphery region P from the portion of the semiconductor substrate in the cell region C. A width of the third trench 103 may be greater than a width of each of the plurality of first trenches 101.

In some embodiments, the operation S40 in which the second mask layer in the cell region may be removed and the plurality of second trenches may be formed in the portion of the semiconductor substrate in the cell region, may include the following operations.

Firstly, the second mask layer in the cell region may be removed.

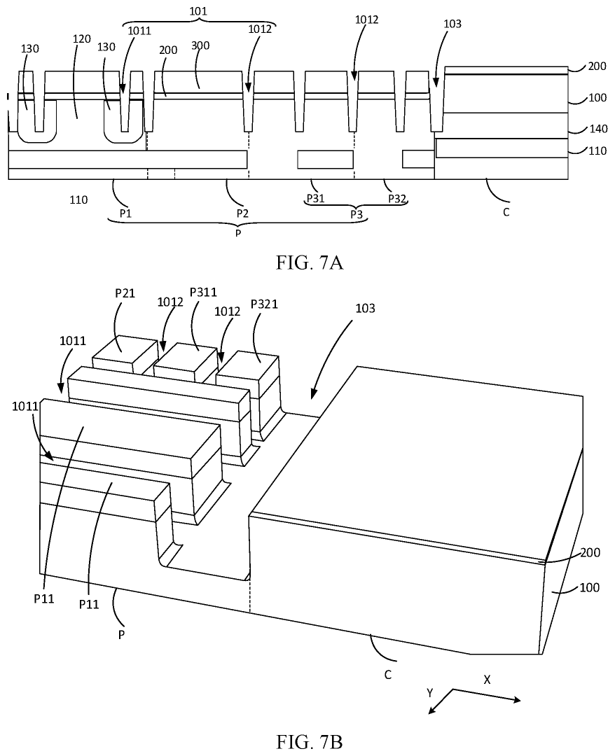

As shown in FIGS. 7A and 7B, FIG. 7A is a structural schematic view of removing the second mask layer from the cell region according to an embodiment of the present disclosure; and FIG. 7B is a perspective view of the cell region having the second mask layer removed as shown in FIG. 7A, being viewed from a second viewing angle, according to an embodiment of the present disclosure.

As shown in FIGS. 7A and 7B, based on FIGS. 6A and 6B, a protective layer may be formed in the periphery region P to protect the periphery region P, the second mask layer in the cell region C may be removed, and the second mask layer 300 in the periphery region P may be retained. After removing the second mask layer in the cell region C, the protective layer in the periphery region P may be removed.

Subsequently, the plurality of second trenches may be formed, and each of the plurality of second trenches may extend along the second direction.

In the cell region, the plurality of second trenches may be formed from the first mask layer toward the semiconductor substrate to divide the portion of the semiconductor substrate in the cell region into a plurality of cell active areas, and each of plurality of cell active areas may extend along the second direction.

Prior to the above operation, a photoresist layer may be formed, and patterns of the plurality of second trenches may be formed on the photoresist layer.

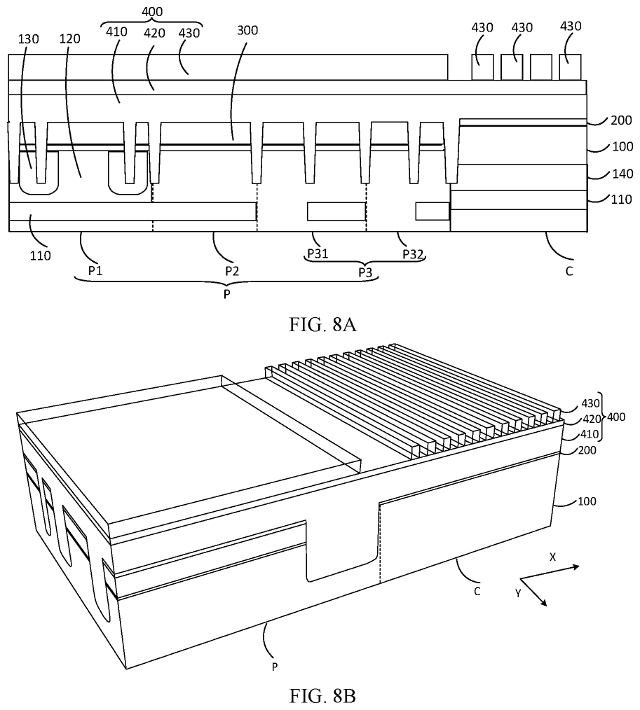

As shown in FIGS. 8A and 8B, FIG. 8A is a structural schematic view of forming the photoresist layer according to an embodiment of the present disclosure; and FIG. 8B is a perspective view of the formed photoresist layer as shown in FIG. 8A, being viewed from a first viewing angle, according to an embodiment of the present disclosure.

As shown in FIGS. 8A and 8B, based on FIGS. 7A and 7B, the photoresist layer 400 may be formed in the cell region C, and the patterns corresponding to the plurality of second trenches 102 may be formed on the photoresist layer 400.

Furthermore, the photoresist layer 400 may include a third mask layer 410, a fourth mask layer 420, and a photoresist layer 430. The third mask layer 410 may fill the plurality of first trenches 101 and the third trench 103 and may cover the semiconductor substrate. The fourth mask layer 420 may cover the third mask layer 410, and the photoresist layer 430 may cover the f fourth mask layer 420. The patterns corresponding to the plurality of second trenches may be formed on a portion of the photoresist layer corresponding to the cell region C, such that the plurality of second trenches 102 may be correspondingly formed in cell region C.

The plurality of second trenches may be formed, and each of the plurality of second trenches may extend along the second direction.

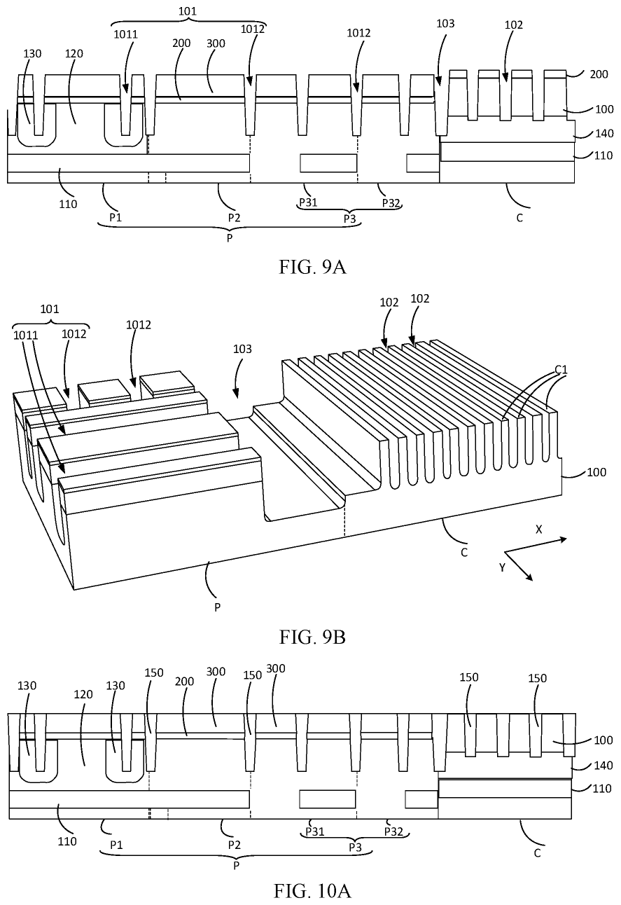

As shown in FIGS. 9A and 9B, FIG. 9A is a structural schematic view of forming the plurality of second trenches according to an embodiment of the present disclosure; and FIG. 9B is a perspective view of the formed plurality of second trenches as shown in FIG. 9A, being viewed from a first viewing angle, according to an embodiment of the present disclosure.

As shown in FIGS. 9A and 9B, based on FIGS. 8A and 8B, the plurality of second trenches 102 may be formed to divide the portion of the semiconductor substrate 100 in the cell region C into a plurality of cell active areas C1, and each of the plurality of cell active areas C1 may extend along the second direction.

In some embodiments, a depth of each of the plurality of second trenches 102 may be less than a depth of each of the plurality of first trenches 101.

In some embodiments, after forming the third trench 103, the second mask layer 300 of the cell region C may be removed, and the portion of the semiconductor substrate in the cell region C may be etched to form the cell active areas of the cell region C. During etching the portion of the semiconductor substrate in the cell region C, the periphery region P may be protected. The third trench 103 may be located between the periphery region P and the cell region C. Etching may be performed at an edge of the third trench 103, i.e., a step may be formed in the third trench 103. As shown in FIG. 9B, the step may be formed in the third trench 103 at a position near the cell region C, and the step and the plurality of second trenches 102 may be formed simultaneously and may have a same depth. In some embodiments, when alignment is controlled accurately, no step may be formed in the third trench.

In some embodiments, the operation S50, in which the isolation material may be formed to fill the plurality of first trenches and the plurality of second trenches and cover the surfaces of the cell region and periphery region, may include following operations.

The isolation structure may be formed. The isolation structure may fill the plurality of second trenches in the cell region, the plurality of first trenches in the periphery region, and the third trench between the periphery region and the cell region.

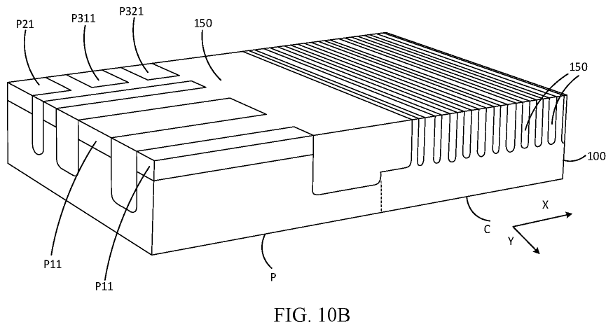

As shown in FIGS. 10A and 10B, FIG. 10A is a structural schematic view of forming the isolation structure according to an embodiment of the present disclosure; and FIG. 10B is a perspective view of the formed isolation structure as shown in FIG. 10A, being viewed from a first viewing angle, according to an embodiment of the present disclosure.

As shown in FIGS. 10A and 10B, based on FIGS. 9A and 9B, the isolation material may be formed and cover the surface of the semiconductor substrate. The isolation material may fill the plurality of first trenches 101, the plurality of second trenches 102, and third trench 103, and may cover the surface of the portion of the semiconductor substrate in the cell region C and the surface of the second mask layer 300 in the periphery region P.

Furthermore, the height of the periphery region and the height of the cell region may be reduced, such that the upper surface of the second mask layer in the periphery region may be aligned and flush with the upper surface of the portion of the semiconductor substrate in the cell region.

As shown in FIGS. 10A and 10B, chemical mechanical polishing may be performed on the isolation material, at least part of the isolation material may be removed, and the first mask layer 200 at the cell region C may be removed. In this way, the portion of the semiconductor substrate 100 in the periphery region C may be exposed, and the supper surface of the remaining second mask layer 300 in the periphery region P may be aligned and flush with the upper surface of the portion of the semiconductor substrate in the periphery region C.

It may be understood that the isolation material remained in the plurality of first trenches 101, the plurality of second trenches 102, and the third trench 103 may serve as an isolation structure 150.

Furthermore, an upper surface of the isolation structure 150 in the cell region C ma be flush with the upper surface of the portion of the semiconductor substrate 100 in the cell region C. The first mask layer 200 and the second mask layer 300 may be remained on the periphery region P of the semiconductor substrate. An upper surface of the second mask layer 300 may be co-planar with the upper surface of the isolation structure 150 in the periphery region P. Therefore, the isolation structure 150 in the periphery region P may be higher than the portion of the semiconductor substrate 100 in the periphery region P.

Specifically, after forming the isolation material to fill the plurality of first trenches 101, the plurality of second trenches 102, and the third trench 103, and covering the periphery region P and the cell region C of the semiconductor substrate, the height of the periphery region P and the cell region C may be reduced. That is, during performing the chemical mechanical polishing on the isolation material, the first mask layer 200 in the cell region C may be removed. When the second mask layer 300 is higher than the portion of the semiconductor substrate in the cell region C, at least part of the second mask layer 300 in the periphery region may be removed. When the second mask layer 300 is lower than the portion of the semiconductor substrate in the cell region C, at least part of the portion of the semiconductor substrate in the cell region may be removed. In this way, the height of the second mask layer 300 in the periphery region P may be consistent with the height of the portion of the semiconductor substrate in the cell region C.

In some embodiments, after forming the first mask layer, the well may be formed in the semiconductor substrate.

As shown in FIGS. 4A and 4B, after forming the first mask layer 200, the first well 110 may be formed in the semiconductor substrate 100. The first well 110 may be located in the portion of the semiconductor substrate in the cell region C and in the portion of the semiconductor substrate in the periphery region P. The first well 110 may be present in the semiconductor substrate in the first type area P1, the second type area P2, the third type area P3, and the cell region C. A second well 120 may be formed and may be located within the first type area P1 of the semiconductor substrate 100. The second well 120 may be higher than the first well 110. The second well 120 may contact the first well 110. A drift region 130 may be formed. The drift region 130 may be located in the first type area P1 of the semiconductor substrate 100. The drift region 130 may be located within the second well 120.

The first well 110 and the second well 120 may have different doping types. That is, doping type of the first well 110 may be opposite to a doping type of the second well 120. For example, when the first well 110 is a deep N-type doped well, i.e., deep N well (DNW), the second well 120 may be a P-type doped well, i.e., P well (PW). In addition, the drift region 130 may be an N-type drift region, i.e., N-drift.

It may be understood that in FIG. 4A, in the second direction, the first well 110 in the third type area I P31 and the first well 110 in the third type area II P32 may be formed in only a portion of the semiconductor substrate corresponding to the third type area I P31 and the third type area II P32. No first well may be formed in another portion of the semiconductor substrate corresponding to the third type area I P31 and the third type area II P32. That is, each of the third type area I P31 and the third type area II P32 may be divided into two parts. The first well 110 may be formed in one of the two parts, and no first well may be formed in the other one of the two parts. That is, the other one of the two parts where no first well is formed may extend along the second direction, and various types of devices, such as NMOS and PMOS, may be formed thereon. Correspondingly, the second type area P2 may be a part that does not extend, and therefore, the first well in the portion of the semiconductor substrate within the second type area P2 may be a continuous structure.

In some embodiments, a third well 140 may be formed in a portion of the semiconductor substrate 100 within the cell region C. The third well 140 may be located above the first well 110. A doping type of the third well 140 is different from the doping type of the first well 110. Therefore, when the first well 110 is the deep N-type doped well (DNW), the third well 140 may be a deep P-type doped well (DPW).

In some embodiments, various types of areas may be divided based on voltage differences.

As shown in 4A, the first type area P1, the second type area P2, and the third type area P3 may be areas with different voltages. For example, the first type area P1 may be a high-voltage area, the second type area P2 may be a medium-voltage area, and the third type area P3 may be a low-voltage area and may include the third type area I P31 and the third type area II P32. It may be understood that the high-voltage area, the medium-voltage area, and the low-voltage area may be determined based on a rated voltage value set for each area. For example, the rated voltage value for the high-voltage area may be set at 32V, the rated voltage value for the medium-voltage area may be set at 8V. Two low-voltage areas may be included, the rated voltage value for the one of the two low-voltage areas may be set at 3.3V, and the rated voltage value for the other one of the two low-voltage areas may be set at 1.1V. Different types of control devices may be formed in areas with different voltages.

In the present embodiment, the semiconductor substrate may be divided into the cell region and the periphery region. The height of the portion of the semiconductor substrate in the periphery region may be reduced. The first mask layer and the second mask layer may be formed on the semiconductor substrate. The plurality of first trenches may be formed in the portion of the semiconductor substrate in the periphery region, the second mask layer in the cell region may be removed. The plurality of second trenched may be formed in the portion of the semiconductor substrate in the periphery region. The isolation material may be formed to fill the plurality of first trenches and the plurality of second trenches and cover the surfaces of the cell region and the periphery region. The height of the periphery region and the height of the cell region may be reduced, such that the upper surface of the second mask layer in the periphery region may be aligned and flush with the height of the portion of the semiconductor substrate in the cell region. The present embodiment provides a method of forming the active area of the cell region and the active area of the periphery region, enabling the storage array, which is to be subsequently formed, to be integrated into traditional logic processes.

The present disclosure further provides a semiconductor device, as shown in FIG. 10B.

The semiconductor device may include: the semiconductor substrate 100, the first mask layer 200 and the second mask layer 300. The semiconductor substrate 100 is divided into the cell region C and the periphery region P. The first mask layer 200 may cover the portion of the semiconductor substrate 100 in the periphery region P, the second mask layer 300 may cover the first mask layer 200. The upper surface of the second mask layer 300 may be aligned and flush with the upper surface of the portion of the semiconductor substrate 100 in the cell region C.

In an embodiment, the semiconductor device may further include: the plurality of first trenches 101, the plurality of second trenches 102, and the isolation structure 150. The plurality of first trenches 101 may be located in the periphery region P of the semiconductor substrate. The plurality of second trenches 102 may be located in the cell region C of the semiconductor substrate. The isolation structure 150 may fill the plurality of first trenches 101 and the plurality of second trenches 102.

The plurality of first trenches 101 may divide the portion of the semiconductor substrate in the periphery region P into the plurality of periphery active areas. The plurality of second trenches 102 may divide the portion of the semiconductor substrate in the cell region C of into the plurality of cell active areas. The plurality of cell active areas may be higher than the plurality of periphery active areas.

In some embodiments, the plurality of first trenches 101 may include the plurality of first sub-trenches 1011 and the plurality of second sub-trenches 1012. The plurality of first sub-trenches 1011 and the plurality of second sub-trenches 1012 may be located in different regions of the periphery region P. The plurality of first sub-trenches 1011 may be located in the first type area P1 of the periphery region P of the semiconductor substrate. Each of the plurality of first sub-trenches 1011 may extend along the first direction. The plurality of first sub-trenches 1011 may divide the portion of semiconductor substrate in the first type area P1 into the plurality of first type active areas P11 extending along the first direction. The plurality of second sub-trenches 1012 may be located in the second type area P2 and third type area P3 of the periphery region P of the semiconductor substrate. Each of the plurality of second sub-trenches 1012 may extend along the second direction. The plurality of second sub-trenches 1012 may divide portions of the semiconductor substrate in the second type area P2 and in the third type area P3 into the second type active area and the plurality of third type active areas.

Specifically, the plurality of first sub-trenches 1011 may divide the first type area P1 into the plurality of periphery active areas extending along the first direction. The plurality of second sub-trenches 1012 may divide the remaining portion of the semiconductor substrate in the periphery region P into the second type area P2 and at least two third type areas P3. The third type area P3 may include the third type area I P31 and the third type area II P32. The third type area I P31 may correspondingly have the third type active area I P311, and the third type area II P32 may correspondingly have the third type active area II P321. That is, in the portion of the semiconductor substrate out of the first type area P1, the second type active area P21, the third type active area I P311, and the third type active area II P321 may be sequentially arranged.

In some embodiments, the semiconductor device may further include the third trench 103.

The third trench 103 may extend along the second direction to separate the cell region C of the semiconductor substrate from the periphery region P of the semiconductor substrate.

In some embodiments, the isolation structure 150 may further fill the third trench 103 disposed between the periphery region P and the cell region C.

In some embodiments, the semiconductor device may further include the first well 110, the second well region 120, and the drift region 130. The first well 110 may be located in the portion of the semiconductor substrate in the cell region C and the portion of the semiconductor substrate in the periphery region P. The second well 120 may be located in the portion of the semiconductor substrate within the first type area P1. The second well 120 may be higher than the first well 110 and may contact the first well 110. The drift region 130 may be located in the portion of the semiconductor substrate within the first type area P1, and the drift region 130 may be located within the second well 120.

In some embodiments, the depth of each of the plurality of second trenches 102 may be less than the depth of each of the plurality of first trenches 101, such that the depth of the isolation structure in the cell region P may be less than the depth of the isolation structure in the periphery region C.

In the present embodiment, the semiconductor device is provided and may include: the semiconductor substrate, the first mask layer, and the second mask layer. The semiconductor substrate may be divided into the cell region and the periphery region. The first mask layer may cover a portion of the semiconductor substrate in the periphery region, the second mask layer may cover the first mask layer. The height of the second mask layer may be consistent with the height of the portion of the semiconductor substrate in the cell region. According to the present embodiment, the active area in the cell region and the active area in the periphery region may be simultaneously formed, facilitating the storage array to be integrated into traditional logic processes.

The above description shows merely embodiments of the present disclosure and does not limit the scope of the present disclosure. Any equivalent structure or equivalent process transformation made based on the content of the specification and drawings of the present disclosure, applied directly or indirectly in other related technical fields, shall be equivalently included within the scope of the present disclosure.

What is claimed is:

1. A method of manufacturing a semiconductor device, comprising:
providing a semiconductor substrate, wherein the semiconductor substrate comprises a cell region and a periphery region;
reducing a height of a portion of the semiconductor substrate in the periphery region, wherein, a plurality of first trenches are formed in the portion of the semiconductor substrate in the periphery region;
forming a plurality of second trenches in a portion of the semiconductor substrate in the cell region;
forming an isolation structure that fills the plurality of first trenches and the plurality of second trenches;
wherein, the plurality of first trenches divide the portion of the semiconductor substrate in the periphery region into a plurality of periphery active areas; the plurality of second trenches divide the portion of the semiconductor substrate in the cell region into a plurality of cell active areas; a height of the plurality of cell active areas is greater than a height of the plurality of periphery active areas.

2. The method according to claim 1, wherein, the forming an isolation structure, comprises:
forming a first mask layer and a second mask layer on the portion of the semiconductor substrate in the periphery region and a portion of the semiconductor substrate in the cell region, forming a plurality of first trenches in the portion of the semiconductor substrate in the periphery region;
removing the second mask layer on the portion of the semiconductor substrate in the cell region and forming a plurality of second trenches in the portion of the semiconductor substrate in the cell region;
forming an isolation material to fill the plurality of first trenches and the plurality of second trenches and to cover surfaces of the cell region and the periphery region;
reducing a height of the periphery region and a height of the cell region to form the isolation structure, wherein an upper surface of the second mask layer in the periphery region is aligned and flush with an upper surface of the portion of the semiconductor substrate in the cell region.

3. The method according to claim 1, wherein,
the plurality of first trenches are formed; and in the periphery region, a portion of the plurality of first trenches extends along a first direction, and another portion of the plurality of first trenches extends along a second direction.

4. The method according to claim 3, wherein,
the plurality of first trenches comprise a plurality of first sub-trenches and a plurality of second sub-trenches; each of the plurality of first sub-trenches extends along the first direction, and each of the second sub-trenches extends along the second direction;
the plurality of first sub-trenches are located in a first type area of the periphery region and divide a portion of the semiconductor substrate in the first type area into a plurality of first type active areas extending along the first direction;
the plurality of second sub-trenches are located in a second type area and a third type area of the periphery region and divide a portion of the semiconductor substrate in the second type area and the third type area into a second type active area and a plurality of third type active areas extending along the second direction.

5. The method according to claim 2, wherein, after forming the first mask layer, the method further comprises:
forming a first well in the portion of the semiconductor substrate in the cell region and in the portion of the semiconductor substrate in the periphery region, wherein the first well is present in portions of the semiconductor substrate in the first type area, the second type area, the third type area, and the cell region;
forming a second well in the portion of the semiconductor substrate in the first type area, wherein the second well is higher than the first well and contacts the first well;
forming a drift region in the portion of the semiconductor substrate in the first type area, wherein the drift region is located in the second well.

6. The method according to claim 1, wherein, when forming the plurality of first trenches, the method further comprises:
forming a third trench extending along a second direction to divide the portion of the semiconductor substrate in the cell region from the portion of the semiconductor substrate in the periphery region.

7. The method according to claim 2, wherein the removing the second mask layer on the portion of the semiconductor substrate in the cell region and forming a plurality of second trenches in the portion of the semiconductor substrate in the cell region, comprises:
removing the second mask layer in the cell region;
forming the plurality of second trenches, each of the plurality of second trenches extending along a second direction to divide the portion of the semiconductor substrate in the cell region into a plurality of cell active areas extending along the second direction.

8. The method according to claim 1, wherein, a depth of each of the plurality of second trenches is less than a depth of each of the plurality of first trenches.

9. The method according to claim 1, wherein, the reducing a height of the periphery region and a height of the cell region, comprises:
removing at least a portion of the isolation material, and removing the first mask layer in the cell region to expose the portion of the semiconductor substrate in the cell region, enabling the upper surface of the second mask layer in the periphery region to be aligned and flush with the upper surface of the portion of the semiconductor substrate in the cell region.

10. The method according to claim 4, wherein, the plurality of first type active areas are configured to form a first type of electronic component, the second type active area is configured to form a second type of electronic component, and the plurality of third type active areas are configured to form a third type of electronic component;
a rated voltage set for the plurality of first type active areas, a rated voltage set for the second type active area, and a rated voltage set for the plurality of third type active areas are different from each other.

11. The method according to claim 5, wherein, after forming the first mask layer, the method further comprises:
forming a third well in the portion of the semiconductor substrate in the cell region, wherein the third well is located above the first well; a doping type of the third well is different from a doping type of the first well.

12. The method according to claim 1, wherein the reducing a height of a portion of the semiconductor substrate in the periphery region, comprises:
providing a protective layer on the portion of the semiconductor substrate in the cell region;
etching the portion of the semiconductor substrate in the periphery region; and
removing the protective layer after the etching.

13. The method according to claim 6, wherein, after the forming a third trench, the method further comprises:
forming a step on a side wall of the third trench near the cell region, wherein a depth of the step is the same as a depth of each of the plurality of second trenches.

14. A semiconductor device, comprising:
a semiconductor substrate, wherein the semiconductor substrate comprises a cell region and a periphery region;
a plurality of first trenches, defined in a portion of the semiconductor substrate in the periphery region and dividing the portion of the semiconductor substrate in the periphery region into a plurality of periphery active areas;
a plurality of second trenches, defined in a portion of the semiconductor substrate in the cell region and dividing the portion of the semiconductor substrate in the cell region into a plurality of cell active areas; wherein, a height of the plurality of cell active areas is greater than a height of the plurality of periphery active areas; and
an isolation structure, filled in the plurality of first trenches and the plurality of second trenches.

15. The semiconductor device according to claim 14, further comprising:
a first mask layer and a second mask layer, wherein the first mask layer covers a portion of the semiconductor substrate in the periphery region, the second mask layer covers the first mask layer, and an upper surface of the second mask layer is aligned and flush with an upper surface of a portion of the semiconductor substrate in the cell region.

16. The semiconductor device according to claim 14, wherein,
the plurality of first trench comprises a plurality of first sub-trenches and a plurality of second sub-trenches, each of the plurality of first sub-trenches extends along a first direction, and each of the plurality of second sub-trenches extends along a second direction;
the plurality of first sub-trenches are located in a first type area of the periphery region and divides a portion of the semiconductor substrate in the first type area into a plurality of first type active area extending along the first direction;
the plurality of second sub-trenches are located in a second type area and a third type area of the periphery region and divides a portion of the semiconductor substrate in the second type area and the third type area to form a second type active area and a plurality of third type active areas extending along the second direction.

17. The semiconductor device according to claim 14, further comprising:
a third trench, extending along a second direction and dividing the portion of the semiconductor substrate in the cell region from the portion of the semiconductor substrate in the periphery region,
wherein, the isolation structure further fills the third trench between the periphery region and the cell region.

18. The semiconductor device according to claim 16, further comprising:
a first well, located in the portion of the semiconductor substrate in the cell region and in the portion of the semiconductor substrate in the periphery region;
a second well, located in the portion of the semiconductor substrate in the first type area of the periphery region, wherein the second well is higher than the first well and contacts the first well; and
a drift region, located in the portion of the semiconductor substrate in the first type area, wherein the drift region is disposed within the second well.

19. The semiconductor device according to claim 14, wherein,
a depth of each of the plurality of second trenches is less than a depth of each of the plurality of first trenches, and a depth of a portion of the isolation structure in the cell region is less than a depth of a portion of the isolation structure in the periphery region.

20. The semiconductor device according to 18, further comprising a third well in the portion of the semiconductor substrate in the cell region, wherein the third well is located above the first well; a doping type of the third well is different from a doping type of the first well.
